(19) United States
(12) Patent Application Publication
(10) Pub. No.: US 2022/0414300 A1
(43) Pub. Date: Dec. 29, 2022

(54) ASSET ANALYSIS

(71) Applicant: Baker Hughes Holdings LLC, Houston, TX (US)

(72) Inventors: Matthias Odisio, Dallas, TX (US); Ozge Whiting, Houston, TX (US); Vladimir Shapiro, Newton, MA (US); Taufiq Dhanani, Boston, MA (US); Weiwei Qian, Lexington, MA (US); Diwakar Cherukumilli, Springfield, IL (US); John Passarelli, Boston, MA (US); John Hare, Highland, NY (US); Edvardas Kairiukstis, Boston, MA (US)

(21) Appl. No.: 17/847,414

(22) Filed: Jun. 23, 2022

Related U.S. Application Data
(60) Provisional application No. 63/215,640, filed on Jun. 28, 2021.

(51) Int. Cl. G06F 30/27

(52) U.S. Cl. CPC G06F 30/27

(57) ABSTRACT

A method of analyzing an asset is provided. The method can include receiving first data characterizing an industrial asset. The first data can be acquired via a sensor. The method can also include determining a condition of the industrial asset based on a 3D digital twin of the industrial asset. The 3D digital twin can be generated using second data acquired prior to the first data. The digital twin can include at least one 3D digital instance of at least one component of the industrial asset and a list of components of the industrial asset described according to a pre-defined taxonomy associated with the industrial asset. The method can also include providing the condition of the industrial asset. Related apparatuses, systems, and computer-readable mediums are also provided.

### CROSS-REFERENCE TO RELATED APPLICATIONS

The present application claims priority under 35 U.S.C. § 119 to U.S. Provisional Application No. 63/215,640 entitled “Asset Analysis Platform” filed on Jun. 28, 2021, which is hereby expressly incorporated by reference in its entirety.

### BACKGROUND

Inspection of physical assets (e.g., physical twins) can be performed routinely or on-demand to assess a condition of the asset in regard to a baseline or initial condition of the asset. The initial condition of the asset can characterized using a digital twin of the asset created during an on-boarding phase or as a result of an initial inspection. Inspection data from subsequent inspections performed during scheduled or ad-hoc inspections can be compared to the digital twin to determine conditions of the asset. Media data associated with inspection of one or more assets can be processed to generate a digital twin corresponding to the one or more assets. The digital twin can be used to construct equipment lists, identify data streams associated with the one or more assets, and to provide a visualization element to users seeking insight as to the one or more assets.

### SUMMARY

In one aspect, a method of analyzing an asset is provided. In an embodiment, the method can include receiving, by a data processor. The first data can characterize an industrial asset. The first data can be acquired via a sensor. The method can also include determining, by the data processor, a condition of the industrial asset based on a 3D digital twin of the industrial asset. The 3D digital twin can be generated using second data acquired prior to the first data. The 3D digital twin can include at least one 3D digital instance of at least one component of the industrial asset and a list of components of the industrial asset described according to a pre-defined taxonomy associated with the industrial asset. The method can further include providing, by the data processor, the condition of the industrial asset.

In some embodiments, the first data and/or the second data can include unstructured data. In some embodiments, the unstructured data can include at least one of image data of the industrial asset, video data of the industrial asset, or point cloud data of the industrial asset.

In some embodiments, the method can further include determining, by the data processor, a defect of the industrial asset based on the determined condition of the industrial asset. In some embodiments, the defect can include at least one of a leakage, an emission, or an abnormal state of a component of the industrial asset. In some embodiments, the defect can be determined using a predictive model trained in a machine learning process to receive the condition of the industrial asset and output the defect.

In some embodiments, the list of components can identify characteristics of the industrial asset during normal operation and can include at least one of a location of a component of the industrial asset, a location of the industrial asset, a dimension of a component of the industrial asset, a dimension of the industrial asset, an operating parameter of a component of the industrial asset, or an operating parameter of the industrial asset.

In some embodiments, the 3D digital twin can be provided as a 3D mesh model. In some embodiments, the 3D mesh model is an interactive 3D mesh model configured to receive a user input associated with a portion of the industrial asset depicted in the interactive 3D mesh model and to provide asset data corresponding to a component, a condition, or a defect of the industrial asset responsive to the user input.

Non-transitory computer program products (i.e., physically embodied computer program products) are also described that store instructions, which when executed by one or more processors of one or more computing systems, causes at least one processor to perform operations herein. Similarly, computer systems are also described that may include one or more processors and memory coupled to the one or more processors. The memory may temporarily or permanently store instructions that cause at least one processor to perform one or more of the operations described herein. In addition, methods can be implemented by one or more processors either within a single computing system or distributed among two or more computing systems. Such computing systems can be connected and can exchange data and/or commands or other instructions or the like via one or more connections, including a connection over a network (e.g. the Internet, a wireless wide area network, a local area network, a wide area network, a wired network, or the like), via a direct connection between one or more of the multiple computing systems, etc.

### BRIEF DESCRIPTION OF THE FIGURES

FIG. 1 is a diagram of an exemplary embodiment of a system described according to subject matter herein;

FIG. 2 is a diagram of an exemplary embodiment of a neural network configured for use with the system of FIG. 1 described according to subject matter herein;

FIG. 3 is a process flow diagram illustrating an exemplary embodiment of a method performed by the system of FIG. 1 described according to subject matter herein; and

FIG. 4 is a block diagram of a computing system suitable for use in implementing the system of FIG. 1 described according to subject matter herein.

### DETAILED DESCRIPTION

Visual inspection of assets can be performed and inspection data or survey data can be generated by one or more sensors during inspection of the assets. The inspection or survey data can include media files, such as color image data files or infrared data files. The media files can include unstructured data that can be challenging to process and gain insights from. Often specialized tools or stand-alone platforms are required to process the unstructured data into a format from which more detailed analysis can be performed. Often such platforms do not scale well for processing larger amounts of unstructured data and lack sufficient computing power to rapidly and efficiently process large amounts of unstructured data. Existing platforms also lack the ability to generate multi-dimensional digital twins associated with the inspected assets from the unstructured data.

The digital twin can provide a visual element to which asset data can be linked and presented to users. The digital twin can serve as both an intermediary data structure as well as a viewable data structure that can provide a visual depiction of the asset for users to interact with and gain insight from.

The system and methods described herein can create a 3D digital twin of an asset during an initial on-boarding phase during which initial inspection data can be used to generate a 3D digital twin of the asset. The 3D digital twin can be create once over a lifetime of the asset and/or can be updated throughout the lifetime of the asset when changes are made to the asset. In this way, the 3D digital twin can represent the basis by which inspection data acquired during subsequently performed inspections, e.g., during an inspection phase, can be compared to the 3D digital twin to determine a condition of the asset. Advantageously, the 3D digital twin can provide a digital model of the physical twin, e.g., the physical asset, which can be used to assess conditions or changes of the asset without having to deploy human personnel to the physical asset location.

The inspection data can include unstructured data and the system and methods herein can process the unstructured data into a structured format useful for determining the condition of the asset The unstructured data can include inspection data associated with an asset, such as an industrial asset or the like. In some embodiments, the unstructured data can include inspection data such as media files. The media files can include image data collected in black and white, color (e.g., RGB) and infrared modalities; as well as LIDAR data as a point cloud, and other sensor data.

The system and methods described herein can process the unstructured data by sorting the data into sections or categories of an asset. The system and methods described herein can further process the unstructured data to determine its content and identify portions of an asset to which the data pertains. For example, in some embodiments, the system and methods described herein can determine one or more categories of the asset to which the unstructured data can be associated. The system and methods described herein can further determine defects or conditions of inspected assets. For example, in some embodiments, the system and methods described herein can determine if an industrial asset is emitting a gas or a fluid into the environment. In some embodiments, the defects or conditions can include corrosion or physical conditions of the asset.

The system and methods described herein can be implemented in a cloud-based computing environment including one or more computing devices coupled via a network. Such a cloud-based computing environment can be configured to rapidly scale or add new computing resources based on the processing demand (e.g., the amount of unstructured or structured data received for processing). One or more modules configured with computer-readable and executable instructions (e.g., program code) can receive the unstructured data and orchestrate complex analysis/processing of the data using artificial intelligence and machine learning algorithms. In some embodiments, the artificial intelligence and machine learning algorithms can be trained in a machine learning process to detect and determine one or more defects or condition states associated with the asset.

The system and methods described herein can also generate a three-dimensional (3D) digital twin of the asset that can serve as a data structure for additional data associated with the physical asset, e.g., the physical twin. The additional data stored in the 3D digital twin can include a variety asset specific data, such as inspection data, equipment lists, original equipment manufacturer (OEM) specifications, configuration data, dimensions, operating parameters, and the like. The digital twin can act as an intermediary data structure for use in associating inspection, defect, and/or condition data with the asset under inspection. For example, the digital twin can be used to generate an equipment list of items associated with or included in an asset. In some embodiments, the asset can be identified as a particular type or category of equipment based on the digital twin. In some embodiments, the system and methods described herein can generate digital twins including 3D mesh models of assets based on inspection data acquired via aerial or ground surveillance. In some embodiments, the 3D mesh models can include detailed equipment lists associated with the asset. In some embodiments, the 3D mesh models can be interactive and a user can manipulate the 3D mesh model to receive data corresponding to one or more portions of the asset. Ins some embodiments, the system and methods herein can utilize the 3D digital twin to retrieve status reports about the asset of it's components regarding the integrity, operating status, event status, and any abnormal operations.

In some embodiments, the system and methods described herein can employ 3D digital twins as 3D geospatial maps to associate data streams from fixed and mobile sensors deployed in regard to an asset under inspection. In some embodiments, the 3D geospatial maps and/or the 3D digital twin can provide a visualization element or medium for a variety of user applications.

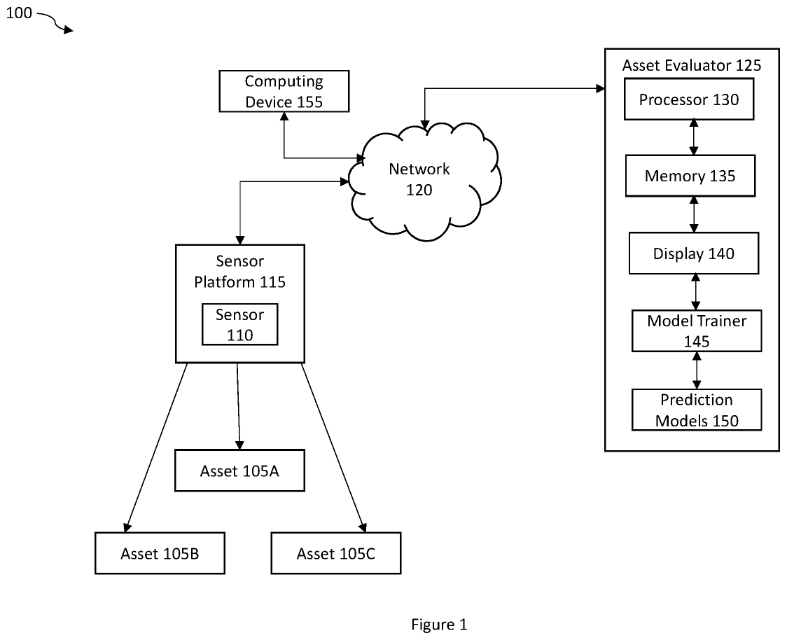

FIG. 1 is a diagram of an exemplary embodiment of a system described according to subject matter herein. As shown in FIG. 1, the asset analysis system 100 can include a plurality of assets 105, a sensor platform 115 including a sensor 110, a network 120, and an asset evaluator 125. The assets 105 can include industrial assets sought to be monitored using the asset analysis system 100. For example, the assets 105 can include industrial equipment, storage tanks, vehicles, aircraft, well machinery, or the like. In some embodiments, the assets 105 can be associated with a location, such as a well pad, configured for oil and gas extraction, production, and refinery operations. Groups of assets, such as a plurality of fluid storage tanks may include oil or water tanks, which can each include component pieces such as thief hatches, manway doors, valves, loading docks, or the like. In some embodiments, the assets 105 can include pipes, valves, pressure vessels, solar panels, compressors, electrical and solar panels, well-heads, and/or pumping equipment.

The sensor 110 can include one or more image sensors, such as a camera. The camera can include visible light cameras, such as a grayscale camera, a black-and-white camera, and/or a color (e.g., RGB) camera. The sensor 110 can also include a camera or imaging device configured to acquire infrared (IR) image data, such as an optical gas imaging (ONG) camera. The data provided by the sensor 110 can include time-series data, such as a video (e.g., a time-sequence of image frames. In some embodiments, the data provided by the sensor 110 can include individual image frames. As used herein, media data can include both individual image frame data and time-series image frame data.

The data provided by the sensors 110 can also include data that has a structured format or an unstructured format. For example, structured data can include an explicit feature name (e.g., “phone number”) and the value (e.g., “866-222-3333). In some embodiments, the structured format data can include an asset category or classification, such as “oil tank” and the value of the “oil tank” can include a height, a width, or a volume of the oil tank. Unstructured data may not include these attributes. For example, image data from sensor 110 may or may not include an oil tank, and, if it does include the oil tank, the data may not include any associated values, such that its height and width are unknown. Unstructured data can require additional processing techniques, such as computer vision, to determine characteristics, properties, values, defects, or conditions of an asset associated with the unstructured data. Another example of unstructured data can include sensor or media data capturing gas emissions or leaks, chemical spills, and/or fluid leaks.

The sensor 110 can be included in a sensor platform 115. In some embodiments, the sensor platform 115 can be a mobile sensor platform capable of positioning the sensor 110 relative to an asset 105 such that media data of the asset 105 can be acquired. In some embodiments, the sensor platform 115 can be fixed or stationing sensor platform that has been advantageously (or randomly) positioned relative to the asset 105 such that media data of the asset 105 can be acquired.

The sensor platform 115 and the computing device 155 can be communicatively coupled to the asset evaluator 125 via a network, such as the network 120. The network 120 can include, for example, any one or more of a personal area network (PAN), a local area network (LAN), a campus area network (CAN), a metropolitan area network (MAN), a wide area network (WAN), a broadband network (BBN), the Internet, and the like. Further, the network 120 can include, but is not limited to, any one or more of the following network topologies, including a bus network, a star network, a ring network, a mesh network, a star-bus network, tree or hierarchical network, and the like.

The asset evaluator 125 can be configured to receive media data from the sensor platform 115 and to determine asset data, including but not limited to a digital twin of the asset 105, as well as, conditions, properties, defects, characteristics of the asset 105. The determined asset data can include defects that can be associated with the mechanical integrity of the asset 105, such as cracks, missing, broken or misplaced pieces of equipment. Additional examples of defects can include fallen solar panels, broken pipes, broken or missing doors, valve handles in a non-expected or undesirable positions (e.g., the valve handle is in an open position when it is expected to be in a closed position).

The asset evaluator 125 can be a computing device including a processor 130, a memory 135 storing non-transitory, computer-readable and executable instructions, and a display 140. The processor 130 can execute the instructions stored in the memory 135 to perform operations described herein associated with the asset analysis system 100. Various data received at and/or generated by the asset evaluator 125 can be provided via the display 140.

The asset evaluator 125 can include a model trainer 145, which can implement a machine learning process and at least one machine learning algorithm to generate a prediction model 150. In some embodiments, the prediction model 150 can include a convolutional neural network (CNN). In some embodiments, the prediction model 150 can include a recurrent neural network (RNN). The model trainer 145 can be configured to train a prediction model using numerous instances of the media data with available ground truth data. For example, the model trainer 145 can use multiple images of oil tanks that include outlines of the oil tanks to train the model to automatically detect oil tanks on previously unseen image data provided for asset data prediction. Input for both model trainer 145 and the prediction model 150 can include image data, such as the structured and/or unstructured data. The inputs can also include prediction results that can include an image mask (e.g., an outline of the oil tank that is overlaid atop of the image of the oil tank). In some embodiments, the inputs can include a list of coordinates of a polygon associated with the image mask.

The asset evaluator 125 can be configured to generate a digital twin of a particular asset 105. A list of assets 105 can be provided to the asset evaluator 125 or stored in a memory 135. The list of assets can be associated with an asset taxonomy classifying the asset by one or more attributes, such as an asset type, an asset location, an asset class, an asset size, or the like. For each asset 105 in the list of assets, the asset evaluator 125 can generate a digital twin corresponding to the asset 105. A digital twin is a digital replica of a physical asset, environment, and/or a system. Digital twins can be used to project physical objects or configurations of physical objects into a digital environment. Digital twins can provide a three-dimensional model or digital representation of an asset, such as an oil tank, as well as the dimensions that may be associated with the oil tank. Digital twins can be used to provide a consistent digital representation of a particular asset in a physical environment.

The digital twin can be output for display, such as on display 140 included in system 100 shown in FIG. 1. The generated digital twin can be provided or output and stored locally in a memory 135 or storage component coupled to the processor 130. In some embodiments, the generated digital twin can be stored remotely from the system 100 and/or the processor 145, such as on computing device 155. The digital twin can be provided for import in other modeling or computer-aided design (CAD) environments or workflows.

The digital twin can include a 3D model that has shapes, volumes, dimensions, and associated measurements that are the same as those of the asset 105. In some embodiments, the 3D model can include a 3D mesh model. The asset evaluator 125 (and/or the computing device 155) can include digital twin visualization tools that can allow user interaction with the 3D model. For instance, by positioning a cursor on the 3D model the user can be provided with coordinates, state, or other asset data associated with the portion of the asset corresponding to the cursor location on the 3D model. The digital twin visualization tools can include functionality to provide asset measurements in real-world coordinate systems. The digital twin visualization tools can provide interactive exploration of the 3D model, allowing a user to rotate, shift, and zoom in/out of the 3D model. In this way, the digital twin visualization tools can enable navigation of the asset in the same was as a person would do in the real world. In some embodiments, the digital twin visualization tools can include interactive video players. Data associated with the 3D model (and thus the asset) may be available during the interactive exploration and also offline. For example, the asset data associated with 3D model can be provided in web pages, data tables, and/or reports.

The digital twin model can also include 3D geospatial maps to coordinate data streams associated with one or more sensors 110. For example, a 3D geospatial map can be created using photogrammetry. This allows the creation of the 3D model (e.g., the digital twin) in actual real-world coordinate systems and can enable the measurement and calculation of sizes, volumes, areas, and quantities in units of measure associated with the real-world coordinate system. In this way, a user can make measurements using the digital twin without visiting the corresponding physical asset to make the measurements, thus saving manpower, resources, and reducing exposure to potentially hazardous environments.

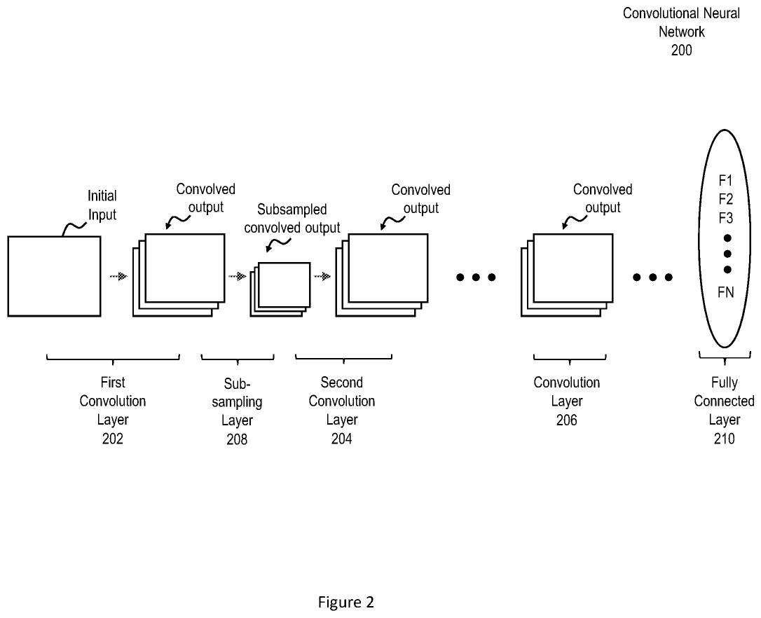

FIG. 2 is a diagram of an exemplary embodiment of a neural network configured for use with the system of FIG. 1 described according to subject matter herein.

In some embodiments, the asset analysis system 100 can implement at least one machine learning model (e.g., at least one multilayer perceptron (MLP), at least one convolutional neural network (CNN), at least one recurrent neural network (RNN), at least one autoencoder, at least one transformer, and/or the like). In some examples, the asset analysis system 100 can implement at least one machine learning model alone or in combination with one or more additional computing systems coupled to the asset analysis system 100 via a network. In some examples, the asset analysis system 100 can implement at least one machine learning model as part of a pipeline (e.g., a pipeline for identifying one or more characteristics, conditions, properties, or defects of an asset and/or the like). An example of an implementation of a machine learning model is included below with respect to FIG. 2.

Memory 135 stores data that is transmitted to, received from, and/or updated by the asset evaluator 125. In some examples, memory 135 includes a storage component, such as a database that stores data and/or software related to the operation and uses of the asset analysis system 100. In some embodiments, memory 135 stores data associated with assets 105, sensor platform 115, model trainer 145, and prediction models 150.

Referring now to FIG. 2, illustrated is a diagram of an implementation of a machine learning model. More specifically, illustrated is a diagram of an implementation of a convolutional neural network (CNN) 200. Although FIG. 2 is described in the context of a CNN, other predictive models can be envisioned. For purposes of illustration, the following description of CNN 200 will be described with respect to an implementation of CNN 200 by asset analysis system 100. However, it will be understood that in some examples CNN 200 (e.g., one or more components of CNN 200) is implemented by other systems different from, or in addition to, the asset analysis system 100. While CNN 200 includes certain features as described herein, these features are provided for the purpose of illustration and are not intended to limit the present disclosure.

CNN 200 includes a plurality of convolution layers including first convolution layer 202, second convolution layer 204, and convolution layer 206. In some embodiments, CNN 200 includes sub-sampling layer 208 (sometimes referred to as a pooling layer). In some embodiments, sub-sampling layer 208 and/or other subsampling layers have a dimension (i.e., an amount of nodes) that is less than a dimension of an upstream system. By virtue of sub-sampling layer 208 having a dimension that is less than a dimension of an upstream layer, CNN 200 consolidates the amount of data associated with the initial input and/or the output of an upstream layer to thereby decrease the amount of computations necessary for CNN 200 to perform downstream convolution operations. Additionally, or alternatively, by virtue of sub-sampling layer 208 being associated with (e.g., configured to perform) at least one subsampling function, CNN 200 consolidates the amount of data associated with the initial input.

The model trainer 145 performs convolution operations based on asset evaluator 125 providing respective inputs and/or outputs associated with each of first convolution layer 202, second convolution layer 204, and convolution layer 206 to generate respective outputs. In some examples, model trainer 145 implements CNN 200 based on asset evaluator 125 providing data as input to first convolution layer 202, second convolution layer 204, and convolution layer 206. In such an example, asset evaluator 125 provides the data as input to first convolution layer 202, second convolution layer 204, and convolution layer 206 based on asset evaluator 125 receiving data from one or more different systems (e.g., sensor platform 115).

In some embodiments, asset evaluator 125 provides data associated with an input (referred to as an initial input) to first convolution layer 202 and asset evaluator 125 generates data associated with an output using first convolution layer 202. In some embodiments, the asset evaluator 125 provides an output generated by a convolution layer as input to a different convolution layer. For example, the asset evaluator 125 provides the output of first convolution layer 202 as input to sub-sampling layer 208, second convolution layer 204, and/or convolution layer 206. In such an example, first convolution layer 202 is referred to as an upstream layer and sub-sampling layer 208, second convolution layer 204, and/or convolution layer 206 are referred to as downstream layers. Similarly, in some embodiments asset evaluator 125 provides the output of sub-sampling layer 208 to second convolution layer 204 and/or convolution layer 206 and, in this example, sub-sampling layer 208 would be referred to as an upstream layer and second convolution layer 204 and/or convolution layer 206 would be referred to as downstream layers.

In some embodiments, the asset evaluator 125 processes the data associated with the input provided to CNN 200 before the asset evaluator 125 provides the input to CNN 200. For example, the asset evaluator 125 processes the data associated with the input provided to CNN 200 based on the asset evaluator 125 normalizing sensor data (e.g., image data received from the sensor platform 115 and sensor 110, and/or the like).

In some embodiments, CNN 200 generates an output based on the asset evaluator 125 performing convolution operations associated with each convolution layer. In some examples, CNN 200 generates an output based on the asset evaluator 125 performing convolution operations associated with each convolution layer and an initial input. In some embodiments, the asset evaluator 125 generates the output and provides the output as fully connected layer 210. In some examples, the asset evaluator 125 provides the output of convolution layer 206 as fully connected layer 210, where fully connected layer 200 includes data associated with a plurality of feature values referred to as F1, F2 . . . FN. In this example, the output of convolution layer 206 includes data associated with a plurality of output feature values that represent a prediction.

In some embodiments, the asset evaluator 125 identifies a prediction from among a plurality of predictions based on the model trainer 145 identifying a feature value that is associated with the highest likelihood of being the correct prediction from among the plurality of predictions. For example, where fully connected layer 210 includes feature values F1, F2, . . . FN, and F1 is the greatest feature value, the model trainer 145 identifies the prediction associated with F1 as being the correct prediction from among the plurality of predictions. In some embodiments, the model trainer 145 trains CNN 200 to generate the prediction. In some examples, the model trainer 145 trains CNN 200 to generate the prediction based on the asset evaluator 125 providing training data associated with the prediction to CNN 200. The trained prediction model can then be deployed as a trained prediction model 150.

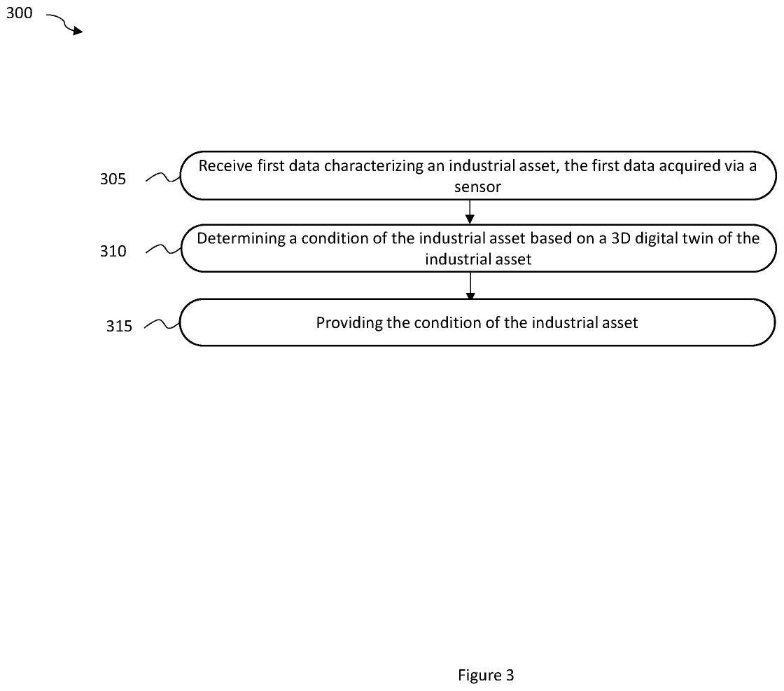

FIG. 3 is a process flow diagram illustrating an exemplary embodiment of a method 300 performed by the system 100 of FIG. 1 according to subject matter herein. The method 300 can include, at 305, receiving first data characterizing an industrial asset 105. The first data can include structured or unstructured data that can be acquired via sensor 110. In some embodiments, the data can include image data of the industrial asset.

In some embodiment, the first data can include inspection data that is received during an inspection of the industrial asset. The inspection results or data can be compared against normal or expected operating conditions of the industrial asset, including arrangement of equipment items or asset components, that are embodied in a digital twin of the industrial asset in order to identify anomalies/defects, etc.

At 310, a condition of the industrial asset 105 can be determined based on a 3D digital twin of the industrial asset. The 3D digital twin can be generated using second data that can be acquired prior to the first data. For example, the second data can include data that is acquired during an onboarding phase in which data associated with the industrial asset is used to form a 3D digital twin of the asset as it is known to exist under normal operating conditions or expected, as-designed, or as manufactured specifications. In this way, the first data can be compared against the second data to determine deviations from the normal operating conditions of the industrial asset.

The 3D digital twin can be generated during an onboarding phase. Subsequent versions of the 3D digital twin can be created when the industrial asset has been moved, replaced, modified, or repaired to establish a subsequent baseline of operation to which the first data acquired during the inspection phase can be compared. The 3D digital twin can include computed digital instances of the industrial asset and any components thereof. Second data, such as inspection data of the industrial asset, can be acquired and used to generate a 3D digital twin including a volumetric mesh model of the industrial asset. For example, an aerial drone configured with a camera sensor can be navigated around the asset and photogrammetry methods can be used to generate the 3D digital twin. The 3D digital twin can include geometric primitives in a user-defined dimensional coordinate system that can represent shapes, dimensions, equipment, components, or the like of the industrial asset. The 3D digital twin can act as a mapping of the industrial asset in the non-digital, physical world. For example, the 3D digital twin can include all the locations, dimensions, features, and measurements of the industrial asset in the non-digital, physical world. Thus, the units of measure for any aspect of the industrial asset can be the same between the non-digital, physical world and the 3D digital twin. In this way, the 3D digital twin can represent the most accurate digital data structure of the actual measurements and configuration of the industrial asset.

For example, an industrial asset including one or more cylinders can be represented using a 3D digital twin in which the cylinders are registered as oil tanks. The components or equipment associated with the industrial asset can be selected from an asset taxonomy defining names, descriptions, and specification data associated with the equipment, or component of the industrial asset, or the industrial asset itself. The system 100 can perform the method 300 in a variety of non-limiting industrial applications and thus can employ a variety of different asset taxonomies to characterize and describe the 3D digital twin and the industrial asset. For example, the system and methods here can be used in regard to industrial equipment or assets in oil and gas production environments, offshore platform maintenance operations, underwater operations such as repair or maintenance of a ship, power generation and transmission environments, automotive manufacturing, or the like.

The 3D digital twin can include an improved data structure configured for use in analyzing an asset. The data structure can include a list of equipment, components, or related aspects of the industrial asset. For example, the list can include characteristics of the industrial asset during normal operation, such as a location of a component of the industrial asset, a location of the industrial asset, a dimension of a component of the industrial asset, a dimension of the industrial asset, an operating parameter of a component of the industrial asset, or an operating parameter of the industrial asset. The measurements, locations, dimensions, and related technical specification data of the component or the industrial asset can be provided in the list in the same units and coordinate data systems as they exist in the physical, non-digital structure of the component of the industrial asset.

Using image registration methods, the first data acquired during inspection of the industrial asset can be compared with the 3D digital twin to identify a condition of the industrial asset. If one or more aspects of the first data do not match the corresponding features, such as a location, a position, a dimension, a continuity of border or outline, the industrial asset or the component of the industrial asset captured in the first data can be determined to be defective or otherwise in a configuration that is not as intended or specified.

Based on the determined condition, a predictive model can be used to receive the condition as an input and to output a defect of the industrial asset or a component of the industrial asset. The defect can be predicted as one of a leakage, an emission, or an abnormal state of a component of the industrial asset or the industrial asset.

At 315, the condition of the industrial asset can be provided. For example, the computing device 155 can include a display configured with a user interface at which the 3D digital twin and it's corresponding data, or reports can be visualized and provided for interactive manipulation by a user. In some embodiments, the 3D digital twin can include an interactive 3D digital twin. A user can manipulate the 3D digital twin to explore conditions or defects of the industrial asset. In some embodiments, the system 100 can generate actions and/or notifications based on determined conditions or defects. In some embodiments, the 3D digital twin can be accessed in a multi-tenant configuration. For example, the system 100 can be configured as a cloud computing environment and different users can access the same version of a 3D digital twin independently from one another and without knowledge of access by any of the different users. In some embodiments, the system 100 can be configured in a multi-site configuration. For example, a user can be associated with an organization with hundreds of assets dispersed across multiple different geographic locations. In some embodiments, the system 100 can be configured in a multi-role configuration. For example, the system can be configured to allow permission levels to be configured for roles within an organization. The permission levels can enforce that particular activities, such as making changes to the 3D digital twin, initiating activities, reviewing data, generating reports, or the like, can only be performed by particular approved roles and may not be performed by other unapproved roles.

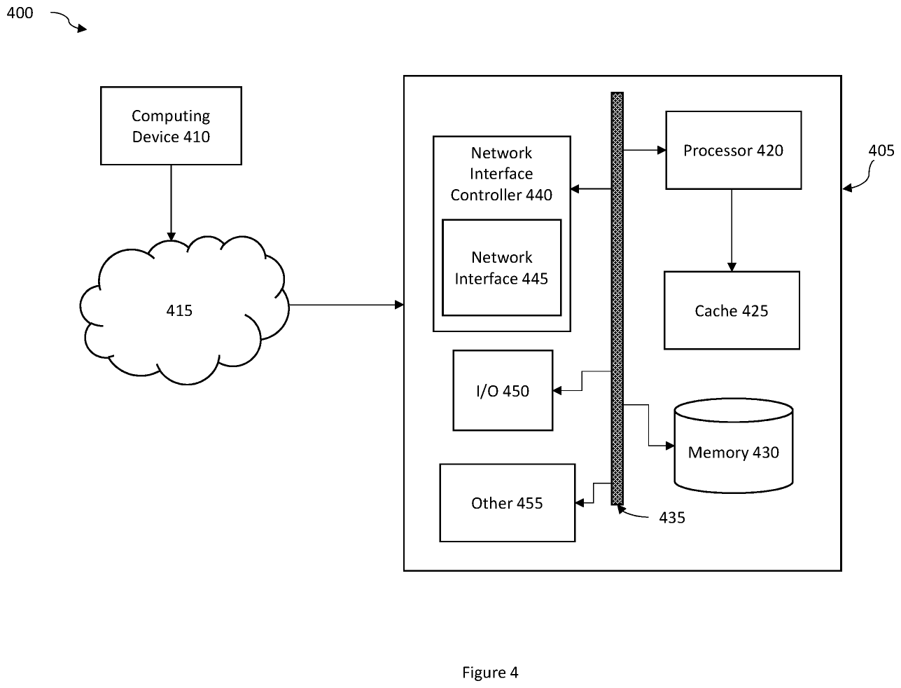

FIG. 4 is a block diagram of a computing system 400 suitable for use in implementing the computerized components of the asset analysis system 100 described herein. In broad overview, the system 400 includes a server computing device 405 coupled to at least one computing device 410 via a network 415. In some embodiments, multiple computing devices 415 can be coupled via one or different networks to server computing device 405. In some embodiments, the computing device 1110 can include one or more predictive models 150, asset lists, asset data, and/or 3D digital twins described in relation to FIGS. 1-3 of the asset analysis system 400. In some embodiments, the computing device 410 can include a personal computing device, such as a smartphone or mobile computing device, configured with an application providing a user interface for evaluating asset data and/or a 3D digital twin.

The server computing device 405 can correspond to the a computing device configured to include the asset evaluator 125 as described in relation to FIG. 1. The computing device 405 can include at least one processor 420 for performing actions in accordance with instructions, and one or more memory devices 425 and/or 430 for storing instructions and data. The illustrated example server computing device 405 includes one or more processors 420 in communication, via a bus 435, with memory 430 and with at least one network interface controller 440 with a network interface 445 for connecting to external devices 410, e.g., a client computing device (such as mobile phone, a smartphone, or the like). The one or more processors 420 are also in communication, via the bus 435, with each other and with any I/O devices at one or more I/O interfaces 450, and any other devices 455. The processor 420 illustrated incorporates, or is directly connected to, cache memory 425. Generally, a processor will execute instructions received from memory. In some embodiments, the server computing device 405 can be configured within a cloud computing environment, a virtual or containerized computing environment, and/or a web-based microservices environment.

In more detail, the processor 420 can be any logic circuitry that processes instructions, e.g., instructions fetched from the memory 430 or cache 425. In many embodiments, the processor 420 is an embedded processor, a microprocessor unit or special purpose processor. The server computing device 405 can be based on any processor, e.g., suitable digital signal processor (DSP), or set of processors, capable of operating as described herein. In some embodiments, the processor 420 can be a single core or multi-core processor. In some embodiments, the processor 420 can be composed of multiple processors.

The memory 430 can be any device suitable for storing computer readable data. The memory 430 can be a device with fixed storage or a device for reading removable storage media. Examples include all forms of non-volatile memory, media and memory devices, semiconductor memory devices (e.g., EPROM, EEPROM, SDRAM, flash memory devices, and all types of solid state memory), magnetic disks, and magneto optical disks. A server computing device 405 can have any number of memory devices 430.

The cache memory 425 is generally a form of high-speed computer memory placed in close proximity to the processor 420 for fast read/write times. In some implementations, the cache memory 425 is part of, or on the same chip as, the processor 420.

The network interface controller 440 manages data exchanges via the network interface 445. The network interface controller 440 handles the physical and data link layers of the Open Systems Interconnect (OSI) model for network communication. In some implementations, some of the network interface controller's tasks are handled by the processor 420. In some implementations, the network interface controller 440 is part of the processor 420. In some implementations, a server computing device 405 has multiple network interface controllers 440. In some implementations, the network interface 445 is a connection point for a physical network link, e.g., an RJ 45 connector. In some implementations, the network interface controller 440 supports wireless network connections and includes a network interface 445 configured as a wireless receiver/transmitter. Generally, a server computing device 405 exchanges data with other computing devices 410 via a network 415 via physical or wireless links to a network interface 445. In some implementations, the network interface controller 440 implements a network protocol such as Ethernet, I2C, cellular data, and/or Bluetooth short-range wireless radio protocols.

The other computing devices 410 can include a similar architecture and components (e.g., a data processor, a memory, a network interface controller, a display, and I/O components) as the server computing device 405. The computing devices 410 can be connected to the computing device 410 via a network interface port 445. The computing device 410 can be a peer computing device, a network device, or any other computing device with network functionality. For example, a computing device 410 can be configured as an administrative terminal of the asset analysis system 100 described herein. In some embodiments, the computing device 410 can include one or more client computing devices configured to provide or view 3D digital twin data and/or asset data, such as equipment lists, asset categories, asset dimension data or the like to the server computing device 405. In some embodiments, the computing device 410 can be a network device such as a hub, a bridge, a switch, or a router, connecting the server computing device 405 to a data network such as the Internet or a private third party data source or network.

In some uses, the I/O interface 450 supports an input device and/or an output device (not shown). In some uses, the input device and the output device are integrated into the same hardware, e.g., as in a touch screen. In some uses, such as in a server context, there is no I/O interface 450 or the I/O interface 450 is not used. In some uses, additional other components 455 are in communication with the server computer device 405, e.g., external devices connected via a universal serial bus (USB).

The other devices 455 can include their own respective I/O interface, external serial device ports, memory, processors, and network interface components as described herein. For example, server computing device 405 can include an interface (e.g., a universal serial bus (USB) interface, or the like) for connecting input devices 455 (e.g., a keyboard, microphone, mouse, or other pointing device), output devices 455 (e.g., video display, speaker, refreshable Braille terminal, or printer), or additional memory devices (e.g., portable flash drive or external media drive). In some implementations an I/O device is incorporated into the server computing device 405 or the computing device 410, e.g., a touch screen on a tablet device. In some implementations, a server computing device 405 includes an additional device 455 such as a co-processor, e.g., a math co-processor that can assist the processor 420 with high precision or complex calculations.

Non-transitory computer program products (i.e., physically embodied computer program products) are also described that store instructions, which when executed by one or more data processors of one or more computing systems, causes at least one data processor to perform operations herein. Similarly, computer systems are also described that may include one or more data processors and memory coupled to the one or more data processors. The memory may temporarily or permanently store instructions that cause at least one processor to perform one or more of the operations described herein. In addition, methods can be implemented by one or more data processors either within a single computing system or distributed among two or more computing systems. Such computing systems can be connected and can exchange data and/or commands or other instructions or the like via one or more connections, including a connection over a network (e.g. the Internet, a wireless wide area network, a local area network, a wide area network, a wired network, or the like), via a direct connection between one or more of the multiple computing systems, etc.

One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and typically interact through a communication network. The relationship of client and server arises by virtue of computer programs running on the respective computers and having a client-server relationship to each other.

These computer programs, which can also be referred to as programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” refers to any signal used to provide machine instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including acoustic, speech, or tactile input. Other possible input devices include touch screens or other touch-sensitive devices such as single or multi-point resistive or capacitive trackpads, voice recognition hardware and software, optical scanners, optical pointers, digital image capture devices and associated interpretation software, and the like.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

1. A method comprising:
receiving, by a data processor, first data characterizing an industrial asset, the first data acquired via a sensor;
determining, by the data processor, a condition of the industrial asset based on a 3D digital twin of the industrial asset, the 3D digital twin generated using second data acquired prior to the first data, the 3D digital twin including at least one 3D digital instance of at least one component of the industrial asset and a list of components of the industrial asset described according to a pre-defined taxonomy associated with the industrial asset; and
providing, by the data processor, the condition of the industrial asset.

2. The method of claim 1, wherein the first data and/or the second data includes unstructured data.

3. The method of claim 2, wherein the unstructured data includes at least one of image data of the industrial asset, video data of the industrial asset, or point cloud data of the industrial asset.

4. The method of claim 1, further comprising
determining, by the data processor, a defect of the industrial asset based on the determined condition of the industrial asset.

5. The method of claim 4, wherein the defect includes at least one of a leakage, an emission, or an abnormal state of a component of the industrial asset.

6. The method of claim 4, wherein the defect is determined using a predictive model trained in a machine learning process to receive the condition of the industrial asset and output the defect.

7. The method of claim 1, wherein the list of components identifies characteristics of the industrial asset during normal operation and includes at least one of a location of a component of the industrial asset, a location of the industrial asset, a dimension of a component of the industrial asset, a dimension of the industrial asset, an operating parameter of a component of the industrial asset, or an operating parameter of the industrial asset.

8. The method of claim 1, wherein the 3D digital twin is provided as a 3D mesh model.

9. The method of claim 8, wherein the 3D mesh model is an interactive 3D mesh model configured to receive a user input associated with a portion of the industrial asset depicted in the interactive 3D mesh model and to provide asset data corresponding to a component, a condition, or a defect of the industrial asset responsive to the user input.

10. The method of claim 1, wherein the 3D digital twin is provided as a 3D geospatial map including a location of the sensor and a location of the industrial asset.

11. A system comprising:
a sensor;
a computing device communicably coupled to the sensor, the computing device including a data processor, a display, and a memory storing non-transitory computer-readable instructions, which when executed by the data processor, cause the data processor to perform operations including
receive first data characterizing an industrial asset, the first data acquired via the sensor;
determine a condition of the industrial asset based on a 3D digital twin of the industrial asset, the 3D digital twin generated using second data acquired prior to the first data, the 3D digital twin including at least one 3D digital instance of at least one component of the industrial asset and a list of components of the industrial asset described according to a pre-defined taxonomy associated with the industrial asset; and
provide the condition of the industrial asset via the display.

12. The system of claim 12, wherein the first data and/or the second data includes unstructured data.

13. The system of claim 13, wherein the unstructured data includes at least one of image data of the asset, video data of the industrial asset, or point cloud data of the industrial asset.

14. The system of claim 12, wherein the instructions further cause the data processor to
determine a defect of the industrial asset based on the determined condition of the industrial asset.

15. The system of claim 15, wherein the defect includes at least one of a leakage, a corrosion, an emission, or an abnormal state of a component of the industrial asset.

16. The system of claim 15, wherein the defect is determined using a predictive model trained in a machine learning process to receive the condition of the industrial asset and output the defect.

17. The system of claim 12, wherein the list of components identifies characteristics of the industrial asset during normal operation and includes at least one of a location of a component of the industrial asset, a location of the industrial asset, a dimension of a component of the industrial asset, a dimension of the industrial asset, an operating parameter of a component of the industrial asset, or an operating parameter of the industrial asset.

18. The system of claim 12, wherein the 3D digital twin is provided as a 3D mesh model.

19. The system of claim 19, wherein the 3D mesh model is an interactive 3D mesh model configured to receive a user input associated with a portion of the industrial asset depicted in the interactive 3D mesh model and to provide asset data corresponding to a component, a condition, or a defect of the industrial asset responsive to the user input.

20. The system of claim 12, wherein the 3D digital twin is provided as a 3D geospatial map including a location of the sensor and a location of the industrial asset.
